(19) United States
(12) Patent Application Publication
(10) Pub. No.: US 2007/0041065 A1
(43) Pub. Date: Feb. 22, 2007

(54) Image processor, image formation apparatus, image processing method, and program

(75) Inventors: Masahiko Kubo, Kanagawa (JP); Michio Kikuchi, Kanagawa (JP); Shinsuke Sugi, Kanagawa (JP); Yoshifumi Takebe, Kanagawa (JP); Hitoshi Ogatsu, Kanagawa (JP)

Correspondence Address: OLIFF & BERRIDGE, PLC, P.O. BOX 19928, ALEXANDRIA, VA, 22320, US

(73) Assignee: FUJI XEROX CO., LTD., TOKYO (JP)

(21) Appl. No.: 11/347,295

(22) Filed: Feb. 6, 2006

(30) Foreign Application Priority Data
Aug. 22, 2005 (JP) 2005-239466

(51) Int. Cl. G03F 3/08

(52) U.S. Cl. 358/521; 358/3.03

(57) ABSTRACT

An image processor for suppressing color variations includes a correction unit and a gradation adjustment unit. The correction unit converts input image data to have higher gray level than that of the input image data, and performs correction processing on the converted image data. The gradation adjustment unit decreases the gray level of the image data on which the correction processing has been performed.

The entire disclosure of Japanese Patent Application No.2005-239466 including the specification, claims, drawings and abstract is incorporated herein by reference in its entirety.

### BACKGROUND

1. Technical Field

This invention relates to an image formation apparatus for suppressing color variations in an image.

2. Related Art

The electrophotographic printer as illustrated in FIG. 1 involves a problem of poor color uniformity in the plane of an image. For example, US 2002/048056 A discloses an image processor for decreasing color nonuniformity in a plane using an n-dimensional DLUT. In this method, nonlinearity of gradation characteristic, multiple transfer characteristic, etc., in the electrophotography can be considered and thus the in-plane uniformity of the printer can be improved substantially.

However, the gradation representation resolution of the printer is limited usually to about eight bits and thus if this method is used, a correction error caused by the gradation representation resolution of the printer exists and if nonuniformity correction processing is performed uniformly for the full face of record paper, pseudo contours caused by the nonuniformity correction are recognized; this is a problem.

FIG. 2 is a drawing to describe a correction error caused by the gradation representation resolution of the printer. In the figure, the horizontal axis of the graph indicates positions in the main scanning direction on record paper and the vertical axis represents lightness. The value on the vertical axis shown in the figure (lightness) indicates process black (black generated by mixing Y, M, and C) of dot values 20% in an electrophotographic printer.

As shown in FIG. 2, if the gradation representation resolution is eight bits, it becomes obvious by checking the correspondence between simulation and correction sample that abrupt color change with a lightness difference of 0.5 or more exists in the areas indicated by the dashed line and thus pseudo contours occur in the part.

It also becomes obvious that-pseudo contours are not recognized by setting the gradation representation resolution of the printer to 10 bits or more according to the result of a correction experiment.

However, if the gradation representation resolution of the printer is simply set to more than eight bits, a problem of degradation of resolution or an increase in costs occurs.

### SUMMARY

In view of the above circumstances, the invention has been made and provides an image formation apparatus for forming an image of higher image quality.

According to an aspect of the invention, an image processor for suppressing color variations includes a correction unit and a gradation adjustment unit. The correction unit converts input image data to have higher gray level than that of the input image data, and performs correction processing on the converted image data. The gradation adjustment unit decreases the gray level of the image data on which the correction processing has been performed.

According to another aspect of the invention, an image formation apparatus includes an image formation unit, a correction unit and a gradation adjustment unit. The correction unit converts input image data to have higher gray level than that of the input image data, and performs correction processing on the converted image data. The gradation adjustment unit decreases the gray level of the image data on which the correction processing has been performed.

According to a still another aspect, an image processing method includes: converting input image data to have higher gray level than that of the input image data; performing correction processing on the converted image data; and decreasing the gray level of the image data on which the correction processing has been performed.

A storage medium is readable by a computer. The storage medium stores a program of instructions executable by the computer to perform a function including: converting input image data to have higher gray level than that of the input image data; performing correction processing on the converted image data; and decreasing the gray level of the image data on which the correction processing has been performed.

The image formation apparatus set forth above can form an image of higher image quality.

### BRIEF DESCRIPTION OF THE DRAWINGS

FIG. 1 is a drawing to show the configuration of a tandem printer 10.

FIG. 2 is a drawing to describe a correction error caused by the gradation representation resolution of a printer.

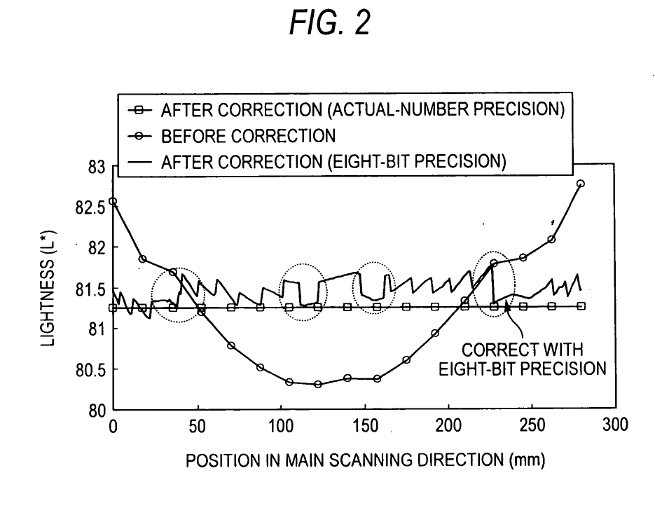

FIG. 3 is a drawing to illustrate the functional configuration of an image processing program 5 executed by an image processor 20 (FIG. 1) for implementing an image processing method according to one embodiment of the invention.

FIG. 4 is a drawing to describe an nonuniformity correction section 520 shown in FIG. 3 in more detail.

FIG. 5 is a drawing to describe a pseudo high gradation processing section 540 shown in FIG. 3 in more detail. FIG. 5A illustrates the functional configuration of the pseudo high gradation processing section 540 and FIG. 5B illustrates diffusion coefficients used for error diffusion.

FIG. 6 is a flowchart to describe the whole operation (S10) of the image processor 20 (image processing program 5).

FIG. 7 is a drawing to describe a second pseudo high gradation processing section 550. FIG. 7A illustrates the functional configuration of the second pseudo high gradation processing section 550, FIG. 7B illustrates an image block extracted by a block extraction section 552, and FIG. 7C illustrates a distribution value table referenced by an error distribution section 558.

FIG. 8 is a flowchart to describe second image processing (S20).

### DETAILED DESCRIPTION

[Hardware Configuration]

First, a printer 10 to which the invention is applied will be discussed.

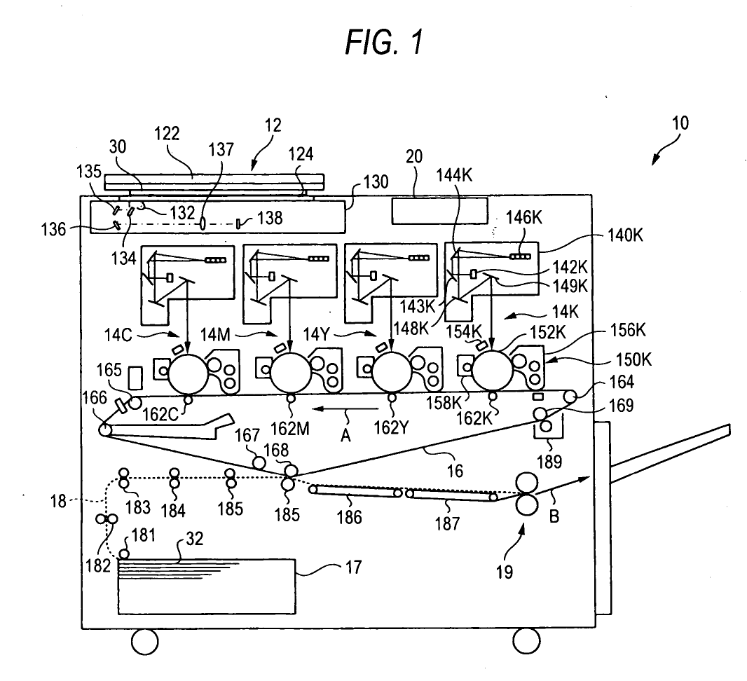

FIG. 1 is a drawing to show the configuration of the tandem printer 10.

As shown in FIG. 1, the printer 10 has an image read unit 12, image formation units 14, an intermediate transfer belt 16, a paper tray 17, a paper transport passage 18, a fuser 19, and an image processor 20. The printer 10 may be a multifunction processing machine including a function of a full-color copier using the image read unit 12 and a function of a facsimile as well as a printer function of printing image data received from a client PC (personal computer).

First, an outline of the printer 10 will be discussed. The image read unit 12 and the image processor 20 are disposed in the upper portion of the printer 10 and function as an image data input unit. The image read unit 12 reads an image displayed on an original and outputs the image to the image processor 20. The image processor 20 performs image processing of color conversion, gradation correction, resolution correction, etc., for the image data input from the image read unit 12 or the image data input from the client PC, etc., through a network such as a LAN, and outputs the processed image data to the image formation units 14.

The image formation units 14 are disposed below the image read unit 12 corresponding to the component colors of a color image. In the example, a first image formation unit 14K, a second image formation unit 14Y, a third image formation unit 14M, and a fourth image formation unit 14C are arranged horizontally with a given spacing from each other along the intermediate transfer belt 16 corresponding to colors of black (K), yellow (Y), magenta (M), and cyan (C). The intermediate transfer belt 16 rotates in the arrow A direction in the figure as an intermediate transfer body and the four image formation units 14K, 14Y, 14M, and 14C form color toner images in order based on the image data input from the image processor 20 and transfer the toner images onto the intermediate transfer belt 16 (primary transfer) at the timing at which the toner images are overlapped on each other. The color order of the image formation units 14K, 14Y, 14M, and 14C is not limited to the order of black (K), yellow (Y), magenta (M), and cyan (C) and any order may be adopted like the order of yellow (Y), magenta (M), cyan (C), and black (K), etc.

The paper transport passage 18 is disposed below the intermediate transfer belt 16. Record paper 32 supplied from the paper tray 17 is transported on the paper transport passage 18 and the color toner images multiple-transferred onto the intermediate transfer belt 16 are transferred in batch (secondary transfer) and the transferred toner image is fixed by the fuser 19 and is ejected to the outside along the arrow B.

Next, the components of the printer 10 will be discussed in more detail.

As shown in FIG. 1, the image read unit 12 has a platen glass 124 on which an original is placed, a platen cover 122 for pressing the original against the top of the platen glass 124, and an image reader 130 for reading the image of the original placed on the platen glass 124. The image reader 130 illuminates the original placed on the platen glass 124 by a light source 132, scans and exposes the reflected light image from the original onto an image read device 138 of CCD, etc., through a reduction optical system including a full rate mirror 134, a first half rate mirror 135, a second half rate mirror 136, and an image formation lens 137, and reads the color material reflected light image of the original 30 by the image read device 138 at a predetermined dot density (for example, 16 dots/mm).

The image processor 20 performs predetermined image processing of shading correction, position shift correction of the original, gamma correction, frame erasion, color/move edit, etc., for the image data read by the image read unit 12.

The image processor 20 in the example performs correction processing for the image data so as to cancel color variations (nonuniformity) occurring in the printed image.

In the example, the color material reflected light image of the original read by the image read unit 12 is three-color original reflectivity data of red (R), green (G), and blue (B) (each eight bits), for example, and is converted into original color material gradation data of four colors, that is, yellow (Y), magenta (M), cyan (C), and black (K) (each eight bits: 256 gradations) by image processing of the image processor 20.

The first image formation unit 14K, the second image formation unit 14Y, the third image formation unit 14M, and the fourth image formation unit 14C (functioning as an image formation unit) are arranged in parallel with a given spacing from each other in the horizontal direction and are almost the same in configuration except that they differ in color of the image to be formed. Therefore, the first image formation unit 14K will be discussed as a representative. The first to fourth image formation units 14 are distinguished from each other with K, Y, M, or C added thereto.

The image formation unit 14K has a light scanner 140K for scanning a laser beam in response to the image data input from the image processor 20 and an image formation device 150K for forming an electrostatic latent image according to the laser beam scanned by the light scanner 140K.

The light scanner 140K modulates a semiconductor laser 142K in response to black (K) image data and emits a laser beam LB (K) from the semiconductor laser 142K in response to the image data. The laser beam LB (K) emitted from the semiconductor laser 142K is applied through a first reflecting mirror 143K and a second reflecting mirror 144K to a rotating polygon mirror 146K and is deflectively scanned by the rotating polygon mirror 146K and is applied through the second reflecting mirror 144K, a third reflecting mirror 148K, and a fourth reflecting mirror 149K onto a photoconductive drum 152K of the image formation device 150K.

The image formation device 150K is made up of the photoconductive drum 152K as an image support for rotating at a predetermined rotation speed along the arrow A direction, a scorotron 154K for primary charging as charging means for uniformly charging the surface of the photoconductive drum 152K, a developing device 156K for developing the electrostatic latent image formed on the photoconductive drum 152K, and a cleaning device 158K. The photoconductive drum 152K is uniformly charged by the scorotron 154K and has an electrostatic latent image formed according to the laser beam LB (K) applied by the light scanner 140K. The electrostatic latent image formed on the photoconductive drum 152K is developed in black (K) toner by the developing device 156K and the toner image is transferred onto the intermediate transfer belt 16. After the toner image transfer process, the remaining toner, paper dust, and the like deposited on the photoconductive drum 152K are removed by the cleaning device 158K.

Other image formation units 14Y, 14M, and 14C also form color toner images of yellow (Y), magenta (M), and cyan (C) and transfer the formed toner images onto the intermediate transfer belt 16 in a similar manner to that described above.

The intermediate transfer belt 16 is placed on a drive roll 164, a first idle roll 165, a steering roll 166, a second idle roll 167, a backup roll 168, and a third idle roll 169 under a given tension. As the drive roll 164 is rotated by a drive motor (not shown), the intermediate transfer belt 16 is circulated at a predetermined speed in the arrow A direction. The intermediate transfer belt 16 is formed like an endless belt by forming a synthetic resin film of polyimide, etc., having flexibility like a belt and connecting both ends of the synthetic resin film formed like a belt by welding, etc.

On the intermediate transfer belt 16, a first primary transfer roll 162K, a second primary transfer roll 162Y, a third primary transfer roll 162M, and a fourth primary transfer roll 162C are disposed at the positions opposed to the image formation units 14K, 14Y, 14M, and 14C respectively, and the color toner images formed on the photoconductive drums 152K, 152Y, 152M, and 152C are multiple-transferred onto the intermediate transfer belt 16 by the primary transfer rolls 162. The remaining toner deposited on the intermediate transfer belt 16 is removed by a cleaning blade or a cleaning brush of a belt cleaning device 189 provided downstream from a secondary transfer position.

Disposed in the paper transport passage 18 are a paper feed roller 181 for taking out record paper 32 from the paper tray 17, a first roller pair 182, a second roller pair 183, and a third roller pair 184 for transporting paper, and a registration roll 185 for transporting the record paper 32 to the secondary transfer position at the predetermined timing.

A secondary transfer roll 185 for being pressed against the backup roll 168 is disposed at the secondary transfer position on the paper transport passage 18, and the color toner images multiple-transferred onto the intermediate transfer belt 16 are secondarily transferred onto the record paper 32 by the pressing force of the secondary transfer roll 185 and an electrostatic force. The record paper 32 onto which the color toner images are transferred is transported to the fuser 19 by a first transport belt 186 and a second transport belt 187.

The fuser 19 performs heating processing and pressurization processing for the record paper 32 onto which the color toner images are transferred, thereby fusing the toner into the record paper 32.

### First Embodiment

The printer 10 of a first embodiment applies higher gradation resolution (in the example, 10-bit precision) than the gradation resolution used in image formation processing (in the example, eight-bit precision) in in-plane nonuniformity correction processing and then restores image data to the gradation resolution applied in the image formation processing (eight-bit precision) at the later stage of the in-plane nonuniformity correction processing.

When restoring image data to the gradation resolution applied in the image formation processing (eight-bit precision), the printer 10 calculates the difference value (value corresponding to the low-order two bits of image data of 10-bit precision) between image data just after the in-plane nonuniformity correction processing (10-bit precision) and the image data converted into the gradation resolution applied in the image formation processing (eight-bit precision), and diffuses the calculated difference value to adjacent pixels.

Accordingly, if the gradation representation resolution of the printer 10 is limited, occurrence of pseudo contours is suppressed.

The first embodiment of the invention will be discussed.

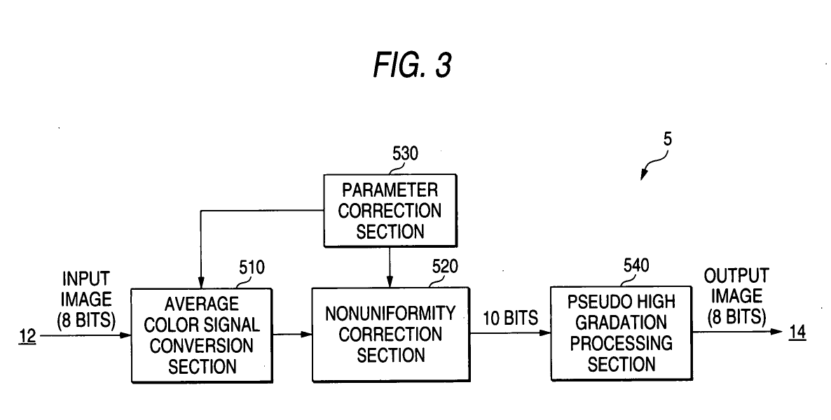

FIG. 3 is a drawing to illustrate the functional configuration of an image processing program 5 executed by the image processor 20 (FIG. 1) for implementing an image processing method according to the first embodiment of the invention.

As illustrated in FIG. 3, the image processing program 5 has an average color signal conversion section 510, an nonuniformity correction section 520, a parameter correction section 530, and a pseudo high gradation processing section 540.

In the image processing program 5, the average color signal conversion section 510 converts input image data into image data made up of L*a*b* and outputs the converted image data to the nonuniformity correction section 520.

The nonuniformity correction section 520 uses a correction parameter provided by the parameter correction section 530 to perform correction processing for the image data input from the average color signal conversion section 510 to suppress color variations occurring in the image. This correction processing converts pixel values so as to cancel color variations occurring in the plane of the image formed by the printer 10. An example of the correction parameter is disclosed in US 2002/048056 A contents of which are incorporated herein by reference in its entirety.

More specifically, the nonuniformity correction section 520 converts the input image data (in the example, eight bits) into image data with higher gray level (in the example, 10 bits) and makes an nonuniformity correction at the precision of the higher gray level.

The nonuniformity correction section 520 in the example calculates color data (CMY) in which the in-plane uniformity in the main scanning direction is corrected, based on the input color data of pixels (L*a*b*) and the position data of the pixels, as described later in detail.

If the in-plane uniformity of the printer 10 changes due to variation with time, replacement of an image support such as a photoconductor, etc., the parameter correction section 530 corrects color conversion parameters (containing the correction parameters applied to the nonuniformity correction) applied by the average color signal conversion section 510 and the nonuniformity correction section 520.

The pseudo high gradation processing section 540 converts the image data input from the nonuniformity correction section 520 (in the example, 10 bits) into the gray level suited for processing at the later stage.

The pseudo high gradation processing section 540 also distributes and diffuses an error occurring before and after the conversion of the gray level (the difference value between the image data before the conversion of the gray level and the image data after the conversion of the gray level) to adjacent pixels.

The pseudo high gradation processing section 540 in the example converts the image data input from the nonuniformity correction section 520 (in the example, 10 bits) into eight-bit image data, outputs the eight-bit image data to the image formation units 14 (FIG. 1), and diffuses the error involved in the conversion of the number of bits (namely, the conversion of the gray level) to the adjacent pixels by an error diffusion method.

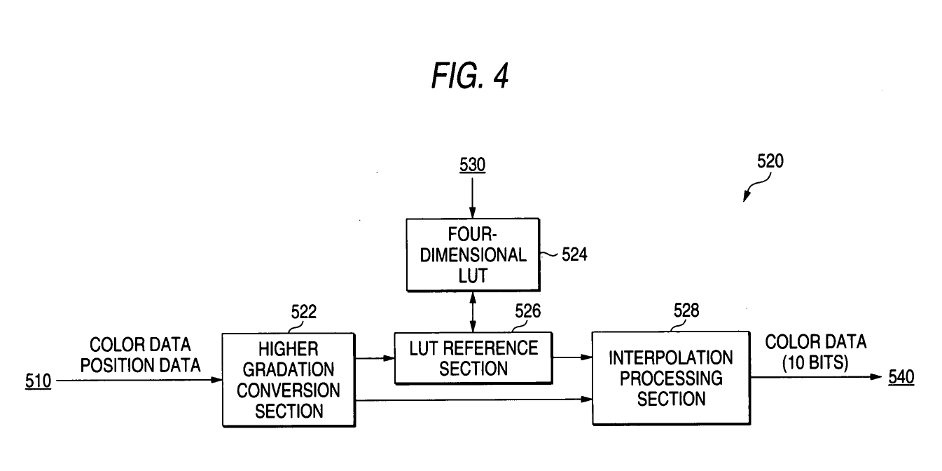

FIG. 4 is a drawing to describe the nonuniformity correction section 520 shown in FIG. 3 in more detail.

As illustrated in FIG. 4, the nonuniformity correction section 520 has a higher gradation conversion section 522, a four-dimensional lookup table (four-dimensional LUT) 524, a lookup table reference section (LUT reference section) 526, and an interpolation processing section 528.

The higher gradation conversion section 522 increase the gray level of the input image data and outputs the image data whose gray level is increased to the LUT reference section 526 and the interpolation processing section 528.

The higher gradation conversion section 522 in the example adds low-order bits (two bits) to the bit string representing the color data of each pixel (L*a*b*) and the bit string representing the position data of each pixel, thereby improving the gradation resolution of the color data and the representation resolution of the position in the image.

The four-dimensional LUT 524 holds the correction parameters of nonuniformity correction provided by the parameter correction section 530 (FIG. 3) as a lookup table.

The four-dimensional LUT 524 in the example holds a four-dimensional table for associating output color data (C value, M value, and Y value) for canceling in-plane nonuniformity occurring in the image formed by the printer 10 with an input data set made up of three pieces of color data (L* value, a* value, and b* value) and position data in the main scanning direction in the image (X coordinate).

To lessen the data size of the table, the four-dimensional LUT 524 in the example stores only the output color data corresponding to the input data sets of lattice points at predetermined intervals without storing the output color data corresponding to all input data sets that can exist. That is, the four-dimensional LUT 524 in the example holds the input data sets thinned out at predetermined intervals and the output color data as a lookup table. Hereinafter, the input data sets existing in the lookup table will be called lattice points.

The LUT reference section 526 references the four-dimensional LUT 524, reads the output color data (C value, M value, and Y value) corresponding to the image data (color data and position data) input from the higher gradation conversion section 522, and outputs the read output color data to the interpolation processing section 528.

If the input image data matches any one of the lattice points held in the four-dimensional LUT 524, the LUT reference section 526 in the example outputs the output color data (C value, M value, and Y value) corresponding to the lattice point to the interpolation processing section 528; if the input image data does not match any of the lattice points held in the four-dimensional LUT 524, the LUT reference section 526 outputs the output color data corresponding to the lattice points in the proximity of the image data to the interpolation processing section 528 together with the values of the lattice points.

The interpolation processing section 528 performs interpolation processing and calculates the output color data corresponding to the input image data. More specifically, the interpolation processing section 528 applies a predetermined interpolation method and calculates the image data subjected to nonuniformity correction (in the example, 10 bits) based on the image data input from the higher gradation conversion section 522 and the output color data and the value of the lattice point input from the LUT reference section 526. The interpolation method is an n-dimensional (in the example, four-dimensional) linear interpolation method, a cube interpolation method of calculating the interpolation value based on the volume of an n-dimensional cube, a tetrahedral interpolation method of calculating the interpolation value based on the volume of an n-dimensional tetrahedral, etc., for example.

Thus, the nonuniformity correction section 520 can use the four-dimensional LUT to convert the input image data into image data with in-plane uniformity in the printer 10 corrected considering the nonlinearity of gradation characteristic, multiple transfer characteristic, etc., in the printer 10.

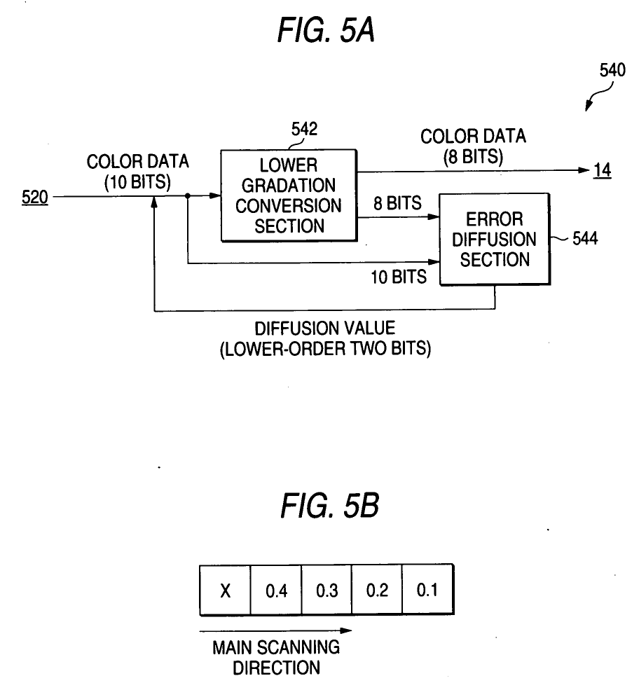

FIG. 5 is a drawing to describe the pseudo high gradation processing section 540 shown in FIG. 3 in more detail; FIG. 5A illustrates the functional configuration of the pseudo high gradation processing section 540 and FIG. 5B illustrates diffusion coefficients used for error diffusion.

As illustrated in FIG. 5A, the pseudo high gradation processing section 540 has a lower gradation conversion section 542 and an error diffusion section 544.

The lower gradation conversion section 542 decreases the gray level of the image data input from the nonuniformity correction section 520 (FIG. 3, FIG. 4) (in the example, 10 bits) to convert the image data into image data of the number of bits suited for processing at the later stage (eight bits) The lower gradation conversion section 542 in the example selects the high-order eight bits of each piece of the input color data (C value, M value, and Y value) and outputs the selected eight bits to the image formation units 14 (FIG. 1) and the error diffusion section 544 as color data.

The error diffusion section 544 calculates the difference value between the image data input from the nonuniformity correction section 520 (in the example, 10 bits) and the image data input from the lower gradation conversion section 542 (in the example, eight bits) and diffuses the calculated difference value in the direction in which the nonuniformity correction is made.

The error diffusion section 544 in the example selects the low-order two bits of the image data input from the nonuniformity correction section 520 as the difference value and diffuses the selected difference value (corresponding to the low-order two bits) in the main scanning direction using the coefficients illustrated in FIG. 5B. That is, the error diffusion section 544 in the example multiplies the low-order two bits of the image data input from the nonuniformity correction section 520 by each coefficient illustrated in FIG. 5B to calculate the diffusion value, and adds the calculated diffusion value to the image data next input from the nonuniformity correction section 520.

As illustrated in FIG. 5B, the error diffusion section 544 in the example distributes the difference value (error) to four pixels downstream in the main scanning direction. The distribution coefficients are 0.4, 0.3, 0.2, and 0.1 in the order from a pixel near the pixel to be processed (given pixel). That is, if a difference value (error) E occurs in the given pixel, the error diffusion section 544 in the example adds diffusion value “0.4×E” to the gradation value (10 bits) of the pixel one pixel downstream in the main scanning direction from the given pixel, adds diffusion value “0.3×E” to the gradation value of the pixel two pixels downstream in the main scanning direction from the given pixel, adds diffusion value “0.2×E” to the gradation value of the pixel three pixels downstream in the main scanning direction from the given pixel, and adds diffusion value “0.1×E” to the gradation value of the pixel four pixels downstream in the main scanning direction from the given pixel.

Accordingly, the image data converted into eight bits becomes image data artificially converted into higher gray level and occurrence of pseudo contours is suppressed. The total value of the coefficients is set to 1 as in the example, whereby variations in the image density accompanying a decrease in the number of bits (conversion from 10 bits to eight bits) are suppressed.

[Operation]

Next, the operation of the image processing program 5 is as follows:

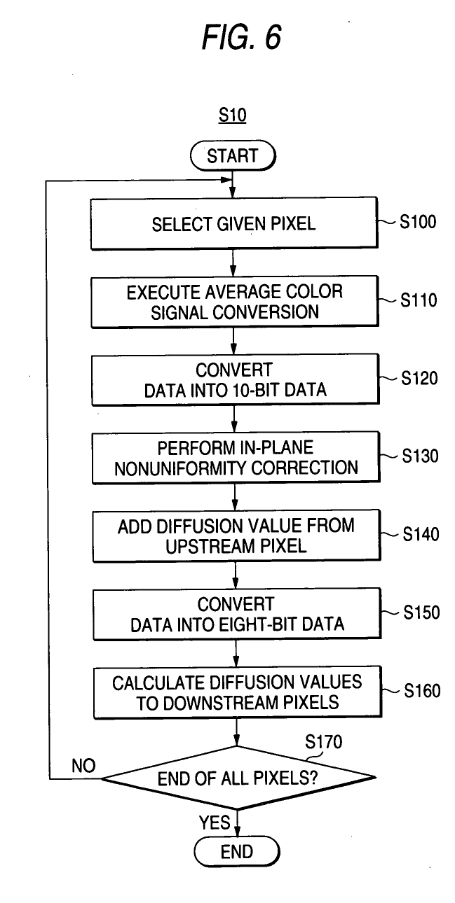

FIG. 6 is a flowchart to describe the whole operation (S10) of the image processor 20 (image processing program 5). In the description of the example, the case where each of the color data and the position data is represented in eight bits (namely, represented in 256 gradations) is taken as a specific example.

As shown in FIG. 6, at step 100 (S100), the image processing program 5 selects an given pixel in the scan order out of the input image data and extracts the color data and the position data of the selected given pixel.

In the description of the example, the case where one pixel at a time is scanned in order from the upstream end in the main scanning direction toward downstream and when the scanning reaches the downstream end of the line, the next line is scanned in a similar manner from the upstream end in the main scanning direction is taken as a specific example.

At step 110 (S110), the average color signal conversion section 510 (FIG. 3) converts the color data of the given pixel into color data of L*a*b*.

The provided color data (L*a*b*) and the position data are input to the nonuniformity correction section 520.

At step 120 (S120), the higher gradation conversion section 522 (FIG. 4) of the nonuniformity correction section 520 adds two bits to the lower part of each of the color data and the position data input from the average color signal conversion section 510 to convert the color data and the position data into the 10-bit color data and the 10-bit position data.

At step 130 (S130), the nonuniformity correction section 520 (FIG. 3, FIG. 4) performs an nonuniformity correction for the input color data with 10-bit precision, in accordance with the position data.

More specifically, the LUT reference section 526 (FIG. 4) refers the four-dimensional LUT 524 and reads the output color data (CMY) corresponding to the color data (L*a*b*) and the position data (X coordinate in the main scanning direction) input from the higher gradation conversion section 522. The read output color data contains at least one set of C, M, and Y values.

The interpolation processing section 528 calculates the interpolation value (CMY) with 10-bit precision based on the color data (CMY) read by the LUT reference section 526. If the number of pieces of read output color data is one (namely, if the input color data and position data match the lattice point), the output color data is output intact.

At step 140 (S140), the error diffusion section 544 (FIG. 5) of the pseudo high gradation processing section 540 adds the diffusion value (10 bits) from the pixel upstream in the main scanning direction (namely, already processed pixel) to the color data (10 bits) input from the nonuniformity correction section 520 (interpolation processing section 528).

At step 150 (S150), the lower gradation conversion section 542 (FIG. 5) selects the high-order eight bits of the color data (10 bits) input from the nonuniformity correction section 520 (interpolation processing section 528) and outputs the selected high-order eight bits to the image formation units 14 (FIG. 1) and the error diffusion section 544 as color data.

At step 160 (S160), the error diffusion section 544 calculates the difference value between the color data input from the nonuniformity correction section 520 (10-bit precision) and the color data input from the lower gradation conversion section 542 (eight-bit precision) and multiplies the calculated difference value by the predetermined diffusion coefficients (FIG. 5B) to calculate the diffusion values to the pixels on the downstream in the main scanning direction.

At step 170 (S170), the image processing program 5 determines whether or not the processing is complete for all pixels. If an unprocessed pixel exists, the image processing program 5 returns to S100 and sets the next given pixel. If the processing is complete for all pixels, the image processing (S10) is terminated.

As described above, the printer 10 in the embodiment performs nonuniformity correction processing in higher gradation representation resolution and thus can suppress occurrence of pseudo contours involved in the nonuniformity correction processing.

The printer 10 restores the image data after subjected to nonuniformity correction to the gray level of image formation processing (eight bits), so that an increase in the memory size and the bus width required for processing at the later stage can be suppressed.

To restore the gray level after the nonuniformity correction, the printer 10 can suppress occurrence of pseudo contours by performing error diffusion processing for artificially converting into higher gradations.

In the embodiment, in-plane nonuniformity in the main scanning direction is corrected and thus the error diffusion section 544 diffuses an error (in the example, the low-order two bits of the color data represented in 10 bits) only in the main scanning direction, but the invention is not limited to the mode. For example, to make nonuniformity correction in the main scanning direction and the subscanning direction, the error diffusion section 544 may diffuse an error in the main scanning direction and the subscanning direction.

### Second Embodiment

Next, a second embodiment of the invention will be discussed.

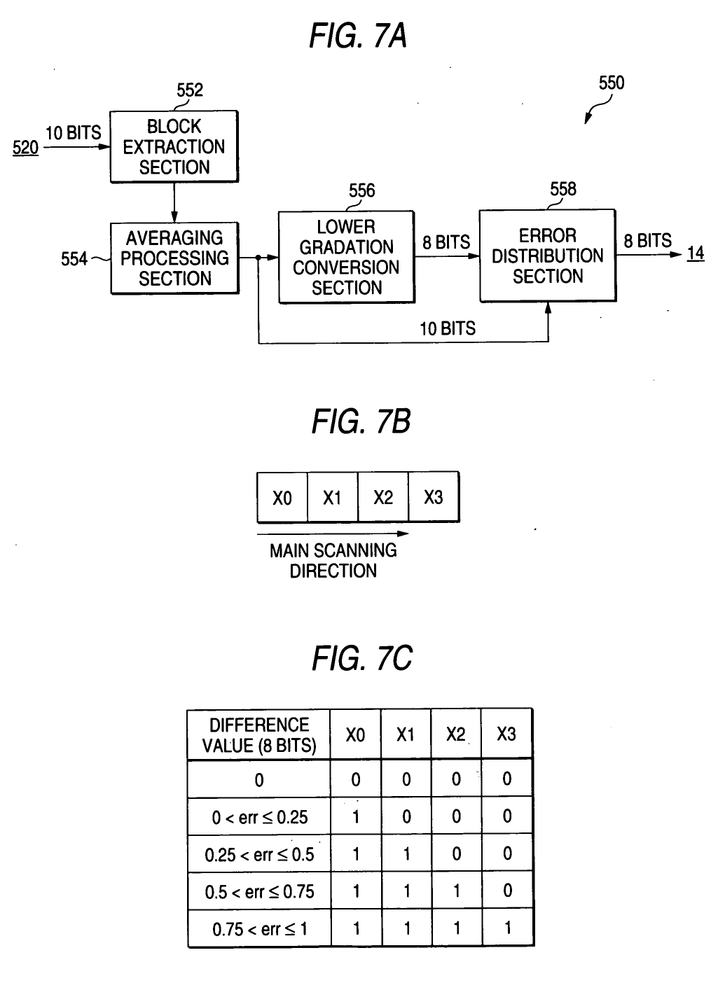

FIG. 7 is a drawing to describe a second pseudo high gradation processing section 550; FIG. 7A illustrates the functional configuration of the second pseudo high gradation processing section 550, FIG. 7B illustrates an image block extracted by a block extraction section 552 in FIG. 7A, and FIG. 7C illustrates a distribution value table referenced by an error distribution section 558 in FIG. 7A.

An image processing program in the second embodiment includes the second pseudo high gradation processing section 550 in place of the pseudo high gradation processing section 540 of the image processing program 5 shown in FIG. 3.

As illustrated in FIG. 7A, the second pseudo high gradation processing section 550 has the block extraction section 552, an averaging processing section 554, a second lower gradation conversion section 556, and the error distribution section 558.

The block extraction section 552 extracts an image block of a predetermined size from input image data. The extracted image block contains a plurality of pixels in the same direction as the direction of nonuniformity correction processing. The image blocks are contiguous to each other and do not overlap.

The block extraction section 552 in the example extracts four pixels successive in the main scanning direction (pixels X0, X1, X2, and X3) as one image block, as illustrated in FIG. 7B.

The averaging processing section 554 calculates an average gradation value about the pixels of the image block extracted by the block extraction section 552 and outputs the calculated average gradation value to the lower gradation conversion section 556 and the error distribution section 558.

The averaging processing section 554 in the example calculates the average gradation value of the four pixels contained in the image block (X0, X1, X2, and X3) with 10-bit precision for each of C, M, and Y values.

The lower gradation conversion section 556 decreases the gray level of the average gradation value calculated by the averaging processing section 554 and converts the average gradation value into the average gradation value of the number of bits suited for processing at the later stage (eight bits)

The lower gradation conversion section 556 in the example selects the high-order eight bits of the average gradation value for each of the input C, M, and Y values and outputs the selected eight-bit average gradation value to the error distribution section 558.

The error distribution section 558 calculates the difference value between the average gradation value input from the averaging processing section 554 (in the example, 10 bits) and the average gradation value input from the lower gradation conversion section 556 (in the example, eight bits) and determines the distribution values to the pixels contained in the image block based on the calculated difference value.

The error distribution section 558 in the example references the distribution value table illustrated in FIG. 7C and reads the distribution values corresponding to the calculated difference value. As illustrated in FIG. 7C, if difference value err is 0, the distribution values become 0 to all pixels contained in the image block. If the difference value err is greater than 0 and is equal to or less than 0.25 (namely, if the total sum of the difference values occurring in the image block is greater than 0 and is equal to or less than 1), the distribution value to the pixel X0 becomes 1 (eight-bit precision) and the distribution values to other pixels X1 to X3 become each 0. Likewise, if the difference value err is greater than 0.25 and is equal to or less than 0.5 (namely, if the total sum of the difference values occurring in the image block is greater than 1 and is equal to or less than 2), the distribution values to the pixels X0 and X1 become each 1 and the distribution values to other pixels X2 and X3 become each 0. If the difference value err is greater than 0.5 and is equal to or less than 0.75 (namely, if the total sum of the difference values occurring in the image block is greater than 2 and is equal to or less than 3), the distribution values to the pixels X0 to X2 become each 1 and the distribution value to the pixel X3 becomes 0. If the difference value err is greater than 0.75 and is equal to or less than 1 (namely, if the total sum of the difference values occurring in the image block is greater than 3 and is equal to or less than 4), the distribution values to all the pixels X0 to X3 become 1.

Thus, the error distribution section 558 determines the distribution values so that the total sum of the difference values occurring in the image block and that of the distribution values almost match, whereby the image density can be kept almost constant.

The error distribution section 558 adds the distribution value determined for each of the pixels contained in the image block to the average gradation value, thereby calculating the gradation value of each of the pixels contained in the image block.

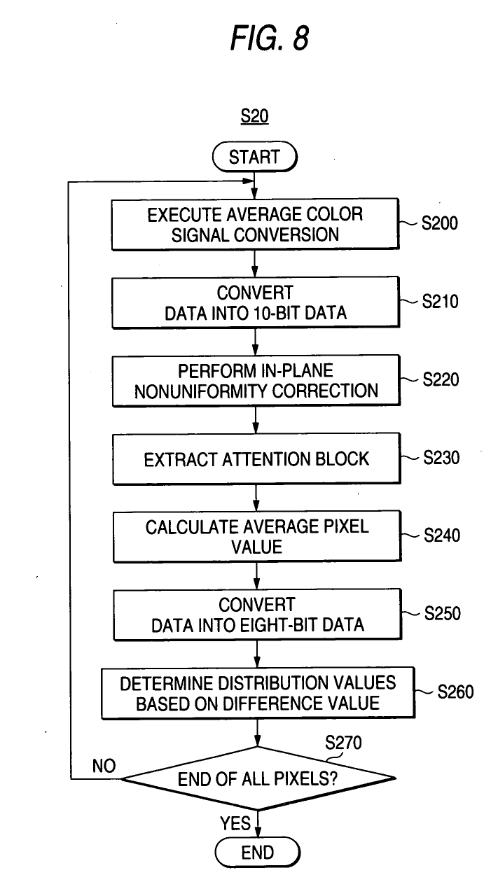

FIG. 8 is a flowchart to describe second image processing (S20). In the description of the example, the case where color data and position data are represented each in eight bits is taken as a specific example.

As shown in FIG. 8, at step 200 (S200), the average color signal conversion section 510 (FIG. 3) converts the color data of the input image into color data made up of L*a*b*.

The provided color data (L*a*b*) and the position data are input to the nonuniformity correction section 520.

At step 210 (S210), the higher gradation conversion section 522 (FIG. 4) of the nonuniformity correction section 520 adds two bits to the lower part of each of the color data and the position data input from the average color signal conversion section 510 to convert the color data and the position data into the 10-bit color data and the 10-bit position data.

At step 220 (S220), the nonuniformity correction section 520 (FIG. 3, FIG. 4) makes an nonuniformity correction responsive to the position data to the input color data with 10-bit precision.

In the example, the described processing is performed for the whole input image.

At step 230 (S230), the block extraction section 552 (FIG. 7) of the pseudo high gradation processing section 550 extracts the image block illustrated in FIG. 7B in the scan order.

Hereinafter, the extracted image block will be called attention block.

At step 240 (S240), the averaging processing section 554 calculates the average gradation value (10 bits) of the pixels X0 to X3 contained in the attention block for each of the color components (C, M, and Y values).

At step 250 (S250), the lower gradation conversion section 556 (FIG. 7) converts the average gradation value of each color component (10-bit precision), calculated by the averaging processing section 554 into the average gradation value with eight-bit precision. Specifically, the lower gradation conversion section 556 selects the high-order eight bits of the 10-bit average gradation value calculated by the averaging processing section 554.

At step 260 (S260), the error distribution section 558 (FIG. 7) calculates the difference value between the average gradation value of each color component calculated by the averaging processing section 554 (10-bit precision) and the average gradation value provided by the lower gradation conversion section 556 (eight-bit precision), reads the distribution values corresponding to the calculated difference value from the distribution value table (FIG. 7C), and adds the read distribution values of the pixels to the average gradation value (eight-bit precision) to calculate the gradation values of the pixels contained in the attention block.

At step 270 (S270), the pseudo high gradation processing section 550 (FIG. 7) determines whether or not the processing is complete for all pixels. If an unprocessed pixel exists, the pseudo high gradation processing section 550 returns to S230 and sets the next given pixel. If the processing is complete for all pixels, the image processing (S20) is terminated.

As described above, the pseudo high gradation processing section 550 in the embodiment calculates the average gradation value of the image block and distributes the error involved in the decrease in the gray level (difference value) to the pixels contained in the image block based on the calculated average gradation value.

At this time, the pseudo high gradation processing section 550 almost matches the total sum of the distribution values with that of errors occurring in the image block, whereby the peripheral density can be saved reliably.

In the embodiment, in-plane nonuniformity in the main scanning direction is corrected and thus the pseudo high gradation processing section 550 diffuses an error (in the example, the low-order two bits of the color data represented in 10 bits) only in the main scanning direction, but the invention is not limited to the mode. For example, to make nonuniformity correction in the main scanning direction and the subscanning direction, the pseudo high gradation processing section 550 may extract an image block containing pixels in the main scanning direction and the subscanning direction and may distribute an error to the whole extracted image block. In other words, the pseudo high gradation processing section 550 in the example can control the error distribution direction and range depending on the shape and the size of the extracted image block.

FIG. 3
510 AVERAGE COLOR SIGNAL CONVERSION SECTION
520 NONUNIFORMITY CORRECTION SECTION
530 PARAMETER CORRECTION SECTION
540 PSEUDO HIGH GRADATION PROCESSING SECTION

FIG. 4
522 HIGHER GRADATION CONVERSION SECTION
524 FOUR-DIMENSIONAL LUT
526 LUT REFERENCE SECTION
528 INTERPOLATION PROCESSING SECTION

FIG. 5
542 LOWER GRADATION CONVERSION SECTION
544 ERROR DIFFUSION SECTION

FIG. 6
S100 SELECT GIVEN PIXEL
S110 EXECUTE AVERAGE COLOR SIGNAL CONVERSION
S120 CONVERT DATA INTO 10-BIT DATA
S130 PERFORM IN-PLANE NONUNIFORMITY CORRECTION
S140 ADD DIFFUSION VALUE FROM UPSTREAM PIXEL
S150 CONVERT DATA INTO EIGHT-BIT DATA
S160 CALCULATE DIFFUSION VALUES TO DOWNSTREAM PIXELS
S170 END OF ALL PIXELS?

FIG. 7
552 BLOCK EXTRACTION SECTION
554 AVERAGING PROCESSING SECTION
556 LOWER GRADATION CONVERSION SECTION
558 ERROR DISTRIBUTION SECTION

FIG. 8
S200 EXECUTE AVERAGE COLOR SIGNAL CONVERSION
S210 CONVERT DATA INTO 10-BIT DATA
S220 PERFORM IN-PLANE NONUNIFORMITY CORRECTION
S230 EXTRACT ATTENTION BLOCK
S240 CALCULATE AVERAGE PIXEL VALUE
S250 CONVERT DATA INTO EIGHT-BIT DATA
S260 DETERMINE DISTRIBUTION VALUES BASED ON DIFFERENCE VALUE
S270 END OF ALL PIXELS?

What is claimed is:

1. An image processor for suppressing color variations, the image processor comprising:
a correction unit that converts input image data to have higher gray level than that of the input image data, and performs correction processing on the converted image data; and
a gradation adjustment unit that decreases the gray level of the image data on which the correction processing has been performed.

2. The image processor according to claim 1, further comprising:
an error diffusion unit that diffuses a difference value in a gradation value between a given pixel of the image data, which has been subjected to the correction processing and is input to the gradation adjustment unit, and a corresponding pixel of the image data whose gray level has been decreased by the gradation adjustment unit, to pixels adjacent to the corresponding pixel.

3. The image processor image processing device according to claim 2, wherein:
the correction unit performs the correction processing of suppressing the color variations in terms of a predetermined direction of the image, and
the error diffusion unit diffuses the difference value in the predetermined direction in which the correction unit performs the correction processing.

4. The image processor image processing device according to claim 2, wherein:
the correction unit performs the correction processing of suppress the color variations in terms of a main scanning direction of the image, and
the error diffusion unit diffuses the difference value in the main scanning direction.

5. The image processor image processing device claim 1, further comprising:
a block extraction unit that extracts image blocks each having a predetermined size from the image data having been subjected to the correction processing by the correction unit;
an averaging processing unit that calculates an average of gradations values in each extracted image block; and
an error diffusion unit, wherein:
the gradation adjustment unit decreases gray level of the average gradation value calculated by the averaging processing unit, and
the error diffusion unit determines gradation values of respective pixels contained in each image block based on (i) a difference value between the average gradation value whose gray level has been decreased by the gradation adjustment unit and the average gradation value calculated by the averaging processing unit and (ii) positions of the respective pixels in each image block.

6. An image formation apparatus for suppressing color variations, the apparatus comprising:
an image formation unit;
a correction unit that converts input image data to have higher gray level than that of the input image data, and performs correction processing on the converted image data; and
a gradation adjustment unit that decreases the gray level of the image data on which the correction processing has been performed.

7. An image processing method comprising:
converting input image data to have higher gray level than that of the input image data;
performing correction processing on the converted image data; and
decreasing the gray level of the image data on which the correction processing has been performed.

8. A storage medium readable by a computer, the storage medium storing a program of instructions executable by the computer to perform a function comprising:
converting input image data to have higher gray level than that of the input image data;
performing correction processing on the converted image data; and
decreasing the gray level of the image data on which the correction processing has been performed.
